(19) United States
(12) Patent Application Publication
(10) Pub. No.: US 2026/0314143 A1
(43) Pub. Date: Oct. 8, 2026

(54) DISPLAY DEVICE

(71) Applicant: LG DISPLAY CO., LTD., Seoul (KR)

(72) Inventor: Sungmoo Kim, Goyang-si (KR)

(21) Appl. No.: 19/637,484

(22) Filed: Apr. 2, 2026

(30) Foreign Application Priority Data
Apr. 2, 2025 (KR) 10-2025-0042844

(51) Int. Cl. H10H 29/39; H10H 29/41

(52) U.S. Cl. CPC H10H 29/39; H10H 29/41

(57) ABSTRACT

A display device includes a substrate, an organic insulating layer disposed on the substrate, a light emitting element disposed on the organic insulating layer, and a connection electrode configured to cover the organic insulating layer in a plan view, and the light emitting element partially overlaps the organic insulating layer in the plan view, and the connection electrode electrically connects a side surface of a part of the light emitting element that does not overlap the organic insulating layer.

### CROSS-REFERENCE TO RELATED APPLICATIONS

Pursuant to 35 U.S.C. § 119 (a), this application claims the benefit of an earlier filing date and right of priority to Korean Patent Application No. 10-2025-0042844 filed on Apr. 2, 2025, in the Ministry of Intellectual Property of the Republic of Korea, the entire disclosure of which is incorporated herein by reference.

### TECHNICAL FIELD

The present disclosure relates to a display device.

### BACKGROUND

Display devices are commonly implemented for various devices such as a monitor of a computer, a TV, or a mobile phone. Display devices can be implemented as an organic light emitting display (OLED) that emits light by itself, and a liquid crystal display (LCD) that requires a separate light source.

Research is being conducted on display devices that have a large display area and have a reduced volume and weight.

### SUMMARY

According to an implementation of the present disclosure, a display device includes a substrate, an organic insulating layer disposed on the substrate, a light emitting element disposed on the organic insulating layer, and a connection electrode configured to cover the organic insulating layer in a plan view, and the light emitting element partially overlaps the organic insulating layer in the plan view, and the connection electrode electrically connects a side surface of a part of the light emitting element that does not overlap the organic insulating layer.

According to another implementation of the present disclosure, a display device includes a substrate on which a first sub pixel, a second sub pixel, and a third sub pixel are disposed, a plurality of organic insulating layers disposed on the substrate in the first sub pixel, the second sub pixel, and the third sub pixel, a plurality of light emitting elements disposed on the plurality of organic insulating layers in the first sub pixel, the second sub pixel, and the third sub pixel, and a connection electrode electrically connecting the plurality of light emitting elements, a part of a lower surface of each of the plurality of light emitting elements may be exposed by not overlapping a corresponding one of the plurality of organic insulating layers, and the connection electrode may be in contact with the part of the lower surface of each of the plurality of light emitting elements that is exposed by not overlapping the corresponding one of the plurality of organic insulating layers.

Other detailed matters of the implementations are included in the detailed description and the drawings.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a schematic block diagram of a display device according to an example implementation of the present disclosure.

FIG. 2A is a partial cross-sectional view of a display device according to an example implementation of the present disclosure.

FIG. 2B is a perspective view of a tiling display device according to an example implementation of the present disclosure.

FIGS. 3A and 3B are enlarged top plan views of sub pixels of a display device according to an example implementation of the present disclosure.

FIG. 4A is a cross-sectional view taken along line A-A′ in FIG. 3A.

FIG. 4B is an enlarged view of an area X of FIG. 4A.

FIG. 4C is a cross-sectional view taken along line B-B′ in FIG. 3A.

FIGS. 5A and 5B are enlarged top plan views of sub pixels of a display device according to another implementation of the present disclosure.

FIGS. 6A and 6B are enlarged top plan views of sub pixels of a display device according to still another implementation of the present disclosure.

FIGS. 7A and 7B are enlarged top plan views of sub pixels of a display device according to still another implementation of the present disclosure.

### DETAILED DESCRIPTION

Implementations of the present disclosure provide a display device using a light emitting diode (LED).

A display device including an LED provides numerous benefits as a next-generation display device. Since the LED is made of an inorganic material rather than an organic material, reliability is excellent, and a lifespan thereof is longer than that of a liquid crystal display device or an organic light emitting display device. Further, the LED has a fast lighting speed, excellent luminous efficiency, and a strong impact resistance so that a stability is excellent and an image having a high luminance can be displayed.

A display device including an LED can be generally manufactured by transferring the LED attached to a temporary substrate to an organic insulating material disposed on a target substrate, and then fixing the LED to the target substrate by the organic insulating material. However, a problem may arise in that the LED may be excessively buried in the organic insulating material such that electrical connection through a lower electrode of the LED is poor or impossible. Further, while the LED comes into contact with the organic insulating material, the LED may be dropped from the target substrate due to a repulsive force of the organic insulating material.

Implementations of the present disclosure can provide a process optimization display device in which a production yield is improved by mitigating a connection failure that may occur when a light emitting element is transferred in a non-contact manner, thereby reducing production energy.

Implementations of the present disclosure can provide a display device capable of stably transferring a light emitting element onto a substrate.

According to some implementations of the present disclosure, the light emitting element partially overlaps the organic insulating layer for fixing the light emitting element on the substrate, and the connection electrode electrically connects a side surface of a part of the light emitting element that does not overlap the organic insulating layer. This can help mitigate the risk of connection failure and provide a process optimization display device capable of reducing production energy by improving the transfer yield of a light emitting element.

According to some implementations of the present disclosure, the organic insulating layer for fixing the light emitting element on the substrate is partially overlapped by the light emitting element and is disposed to be symmetric with respect to the light emitting element, such that the light emitting element may be stably transferred onto the substrate.

The effects according to the present disclosure are not limited to the contents exemplified above, and more various effects are included in the present disclosure.

Advantages and characteristics of the present disclosure and a method of achieving the advantages and characteristics will be clear by referring to example implementations described below in detail together with the accompanying drawings. However, the present disclosure is not limited to the example implementations disclosed herein but will be implemented in various forms. The example implementations are provided by way of example only so that those skilled in the art can fully understand the disclosures of the present disclosure and the scope of the present disclosure.

The shapes, sizes, ratios, angles, numbers, and the like illustrated in the accompanying drawings for describing the example implementations of the present disclosure are merely examples, and the present disclosure is not limited thereto. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated.

The features of various implementations of the present disclosure can be partially or entirely adhered to or combined with each other and can be interlocked and operated in technically various ways, and the implementations can be carried out independently of or in association with each other.

Hereinafter, the present disclosure will be described in detail with reference to the drawings.

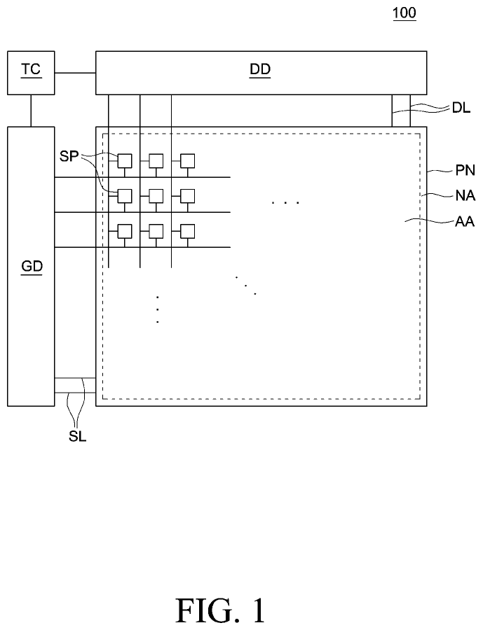

FIG. 1 is a schematic block diagram of a display device according to an example implementation of the present disclosure. In FIG. 1, for the convenience of description, among various components of the display device 100, only a display panel PN, a gate driver GD, a data driver DD, and a timing controller TC are illustrated.

Referring to FIG. 1, a display device 100 includes a display panel PN including a plurality of sub pixels SP, a gate driver GD and a data driver DD which supply various signals to the display panel PN, and a timing controller TC which controls the gate driver GD and the data driver DD.

The gate driver GD supplies a plurality of scan signals to a plurality of scan lines SL according to a plurality of gate control signals provided from the timing controller TC. FIG. 1 illustrates that one gate driver GD is disposed to be spaced apart from one side of the display panel PN. However, the number and arrangement of the gate drivers GD are not limited thereto.

The data driver DD supplies a data voltage to a plurality of data lines DL according to a plurality of data control signals and image data provided from the timing controller TC. The data driver DD may convert image data into a data voltage using a reference gamma voltage and supply the converted data voltage to a plurality of data lines DL.

The timing controller TC aligns image data input from the outside and supplies the image data to the data driver DD. The timing controller TC may generate a gate control signal and a data control signal by using a synchronization signal input from the outside, for example, a dot clock signal, a data enable signal, and a horizontal/vertical synchronization signal. Further, the timing controller TC supplies the generated gate control signal and data control signal to the gate driver GD and the data driver DD, respectively, to control the gate driver GD and the data driver DD.

The display panel PN is configured to display images to a user and includes a plurality of sub pixels SP. In the display panel PN, the plurality of scan lines SL and the plurality of data lines DL may cross each other, and the plurality of sub pixels SP may be formed at intersections of the scan line SL and the data line DL.

In the display panel PN, a display area AA and a non-display area NA may be defined.

The display area AA is an area in which images are displayed in the display device 100. In the display area AA, a plurality of sub pixels SP constituting a plurality of pixels PX and a pixel circuit for driving the plurality of sub pixels SP may be disposed. The plurality of sub pixels SP is a minimum unit constituting the display area AA, and n sub pixels SP may form one pixel PX. In each of the plurality of sub pixels SP, a thin film transistor for driving a corresponding light emitting elements 120 may be disposed. The plurality of light emitting elements 120 may be differently defined depending on the type of the display panel PN. For example, when the display panel PN is an inorganic light emitting display panel PN, the light emitting element 120 may be a light emitting element (LED) or a micro light emitting element (LED).

In the display area AA, a plurality of signal lines for transmitting various signals to the plurality of sub pixels SP is disposed. For example, the plurality of signal lines may include a plurality of data lines DL which supplies a data voltage to each of the plurality of sub pixels SP, a plurality of scan lines SL which supplies a scan signal to each of the plurality of sub pixels SP, and the like. The plurality of scan lines SL may extend in one direction in the display area AA and be connected to the plurality of sub pixels SP, and the plurality of data lines DL may extend in a direction different from the one direction in the display area AA and be connected to the plurality of sub pixels SP. In addition, a power line PL, such as a low potential power line, a high potential power line, and the like may be further disposed in the display area AA, but are not limited thereto.

The non-display area NA is an area where an image is not displayed and may be defined as an area extending from the display area AA. In the non-display area NA, a link line and a pad electrode for transmitting a signal to the sub pixel SP of the display area AA, or a driver IC, such as a gate driver IC or a data driver IC, may be disposed.

In some implementations, the non-display area NA may be located on a rear surface of the display panel PN, that is, a surface on which the sub pixels SP are not disposed or may be omitted, and is not limited as illustrated in the drawing.

In some implementations, a driver such as a gate driver GD, a data driver DD, and a timing controller TC may be connected to the display panel PN in various ways. For example, the gate driver GD may be mounted in the non-display area NA in a gate-in-panel (GIP) manner or mounted between the plurality of sub pixels SP in the display area AA in a gate-in-display area (GIA) manner.

For example, the data driver DD and the timing controller TC are formed on separate flexible film and printed circuit board, and the display panel PN, the data driver DD, and the timing controller TC may be electrically connected by bonding the flexible film and the printed circuit board to the pad electrode formed in the non-display area NA of the display panel PN.

As another example, when the gate driver GD is mounted in the display area AA in the GIA manner and a side line SRL which connects the signal line on the front surface of the display panel PN to the pad electrode on the rear surface of the display panel PN is formed to bond the flexible film and the printed circuit board to the rear surface of the display panel PN, the non-display area NA on the front surface of the display panel PN may be minimized.

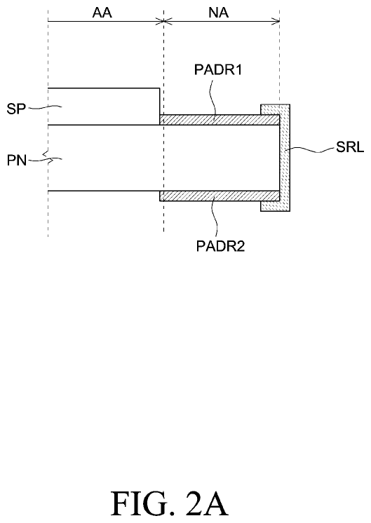

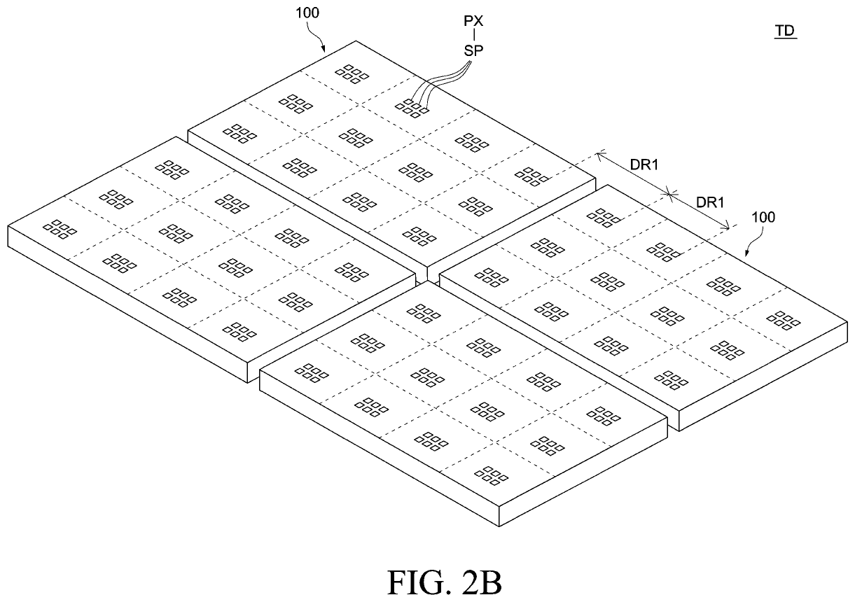

Therefore, when the gate driver GD, the data driver DD, and the timing controller TC are connected to the display panel PN as described above, a zero bezel in which there is substantially no bezel may be implemented. A more detailed description will be described with reference to FIGS. 2A and 2B.

FIG. 2A is a partial cross-sectional view of a display device according to an example implementation of the present disclosure. FIG. 2B is a perspective view of a tiling display device according to an example implementation of the present disclosure.

In the non-display area NA of the display panel PN, a plurality of pad electrodes for transmitting various signals to the plurality of sub pixels SP is disposed. For example, a first pad electrode PADR1 for transmitting a signal to the plurality of sub pixels SP is disposed in the non-display area NA on the front surface of the display panel PN, and a second pad electrode PADR2 electrically connected to a driving component such as a flexible film and a printed circuit board is disposed in the non-display area NA on the rear surface of the display panel PN.

In this case, although not illustrated in the drawings, various signal lines connected to the plurality of sub pixels SP, for example, a scan line SL or a data line DL extend from the display area AA to the non-display area NA to be electrically connected to the first pad electrode PADR1.

Further, the side line SRL is disposed along the side surface of the display panel PN. The side line SRL may electrically connect the first pad electrode PADR1 on the front surface of the display panel PN and the second pad electrode PADR2 on the rear surface of the display panel PN. Therefore, a signal from the driving component on the rear surface of the display panel PN may be transmitted to the plurality of sub pixels SP through the second pad electrode PADR2, the side line SRL, and the first pad electrode PADR1. Accordingly, a signal transmission path is formed from the front surface to the side surface and the rear surface of the display panel PN to minimize an area of the non-display area NA on the front surface of the display panel PN.

Further, referring to FIG. 2B, a tiling display device TD having a large screen may be implemented by connecting a plurality of display devices 100. In this case, when the tiling display device TD is implemented using the display device 100 with a minimized bezel as illustrated in FIG. 2A, a seam area between one display device 100 and another adjacent display device 100 in which an image is not displayed is minimized, thereby improving the display quality.

For example, the plurality of sub pixels SP may form one pixel PX, and an interval DR1 between an outermost pixel PX of one display device 100 and an outermost pixel PX of another display device 100 adjacent to the one display device 100 may be implemented to be equal to an interval DR1 between adjacent pixels PX in the one display device 100. Accordingly, the distance between the outermost pixels PX between the one display device 100 and the adjacent display device 100 is constantly configured to minimize the seam area.

However, FIGS. 2A and 2B are illustrative so that the display device 100 according to the example implementation of the present disclosure may be a general display device with a bezel, but is not limited thereto.

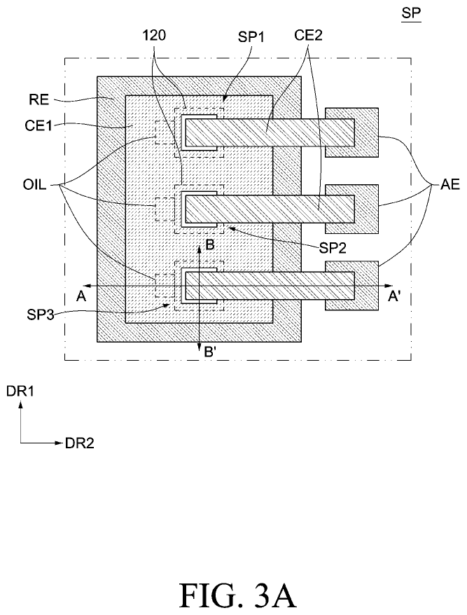

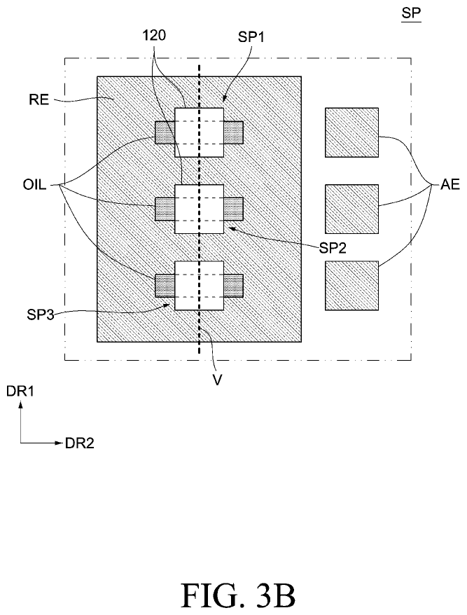

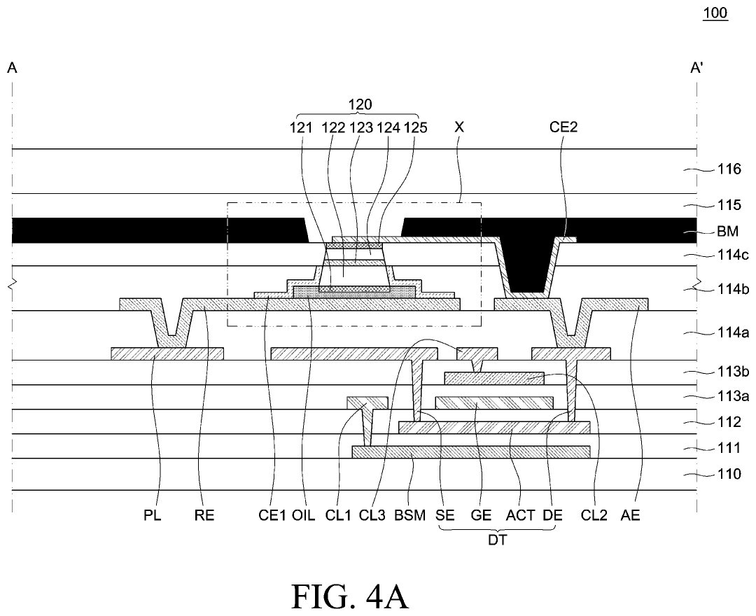

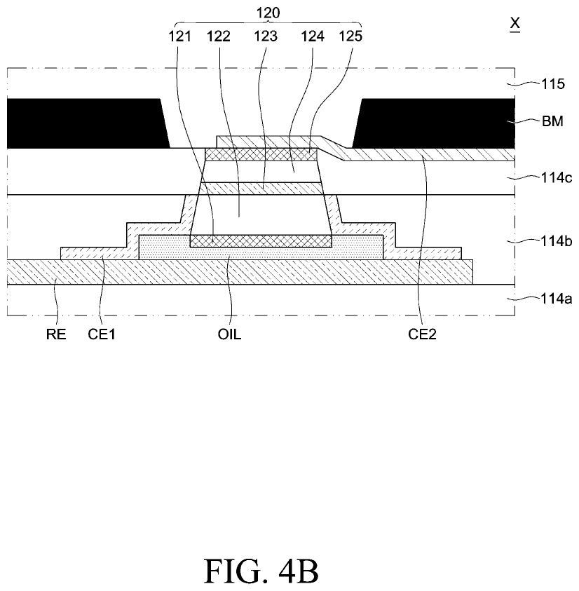

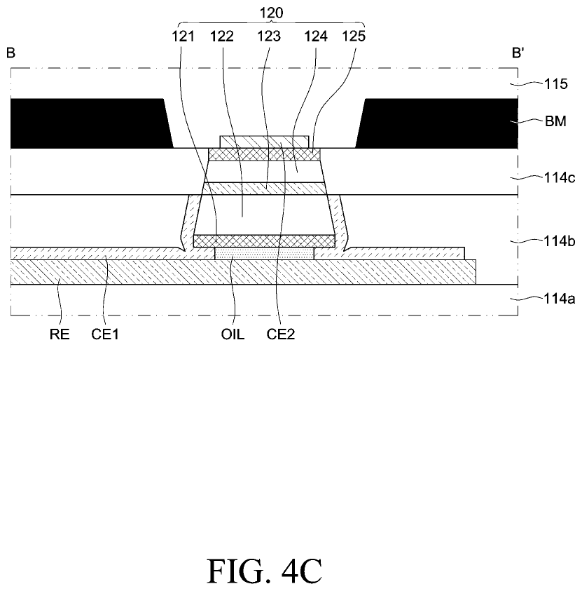

Hereinafter, the sub pixel SP of the display panel PN of the display device 100 according to the implementation of the present disclosure will be described in more detail with reference to FIGS. 3A to 4C.

FIGS. 3A and 3B are enlarged top plan views of sub pixels of a display device according to an example implementation of the present disclosure. FIG. 4A is a cross-sectional view taken along line A-A′ in FIG. 3A. FIG. 4B is an enlarged view of an area X of FIG. 4A. FIG. 4C is a cross-sectional view taken along line B-B′ in FIG. 3A. For convenience of description, FIG. 3A illustrates only a reflective electrode RE, an auxiliary electrode AE, an organic insulating layer OIL, a plurality of light emitting elements 120, a first connection electrode CE1, and a second connection electrode CE2, among various components of the display device. In FIG. 3B, for the convenience of description, only a reflective electrode RE, an auxiliary electrode AE, an organic insulating layer OIL, and a plurality of light emitting elements 120 are illustrated in the same area as in FIG. 3A. In FIG. 4C, for the convenience of description, only a cross section of the same layer as in FIG. 4B is enlarged and illustrated.

Referring to FIGS. 3A to 4C, a plurality of sub pixels SP is disposed in the display area AA. Each of the plurality of sub pixels SP includes a light emitting element 120 and may independently emit light. The plurality of sub pixels SP may be disposed in a matrix while forming a plurality of rows and a plurality of columns, but the example implementations of the present disclosure are not limited thereto.

One pixel PX may include a plurality of sub pixels SP, and the plurality of sub pixels SP may include a first sub pixel SP1, a second sub pixel SP2, and a third sub pixel SP3. For example, any one of the first sub pixel SP1, the second sub pixel SP2, and the third sub pixel SP3 may be a red sub pixel SP, the other one may be a green sub pixel SP, and the rest may be blue sub pixels SP. For example, the first sub pixel SP1 may be a blue sub pixel SP, the second sub pixel SP2 may be a red sub pixel SP, and the third sub pixel SP3 may be a green sub pixel SP. The types of the plurality of sub pixels SP are examples, and the implementations of the present disclosure are not limited thereto.

Referring to FIG. 4A, the first substrate 110 is a member which supports other components of the display device 100 and may be an insulating substrate. For example, the first substrate 110 may be made of glass, resin, or the like. Further, the first substrate 110 may be made of polymer, plastic, or the like. In some implementations, the first substrate 110 may be made of a plastic material having flexibility. A plurality of pixels PX each including a plurality of sub pixels SP may be formed on the first substrate 110 to display an image.

In each of the plurality of sub pixels SP, a light shielding layer BSM is disposed on the first substrate 110. The light shielding layer BSM may block light incident onto the active layer ACT of the driving transistor DT to minimize a leakage current. For example, the light shielding layer BSM is disposed below the active layer ACT of the driving transistor DT to block light incident onto the active layer ACT. If light is irradiated to the active layer ACT, a leakage current is generated, which may degrade the reliability of the driving transistor DT. Accordingly, the light shielding layer BSM for blocking light is disposed on the first substrate 110 to improve the reliability of the driving transistor DT. The light shielding layer BSM may be made of an opaque conductive material, such as copper (Cu), aluminum (Al), molybdenum (Mo), nickel (Ni), titanium (Ti), chromium (Cr), or an alloy thereof, but is not limited thereto.

A buffer layer 111 is disposed on the first substrate 110 and the light shielding layer BSM. The buffer layer 111 may be disposed to cover one surface of the first substrate 110 and reduce penetration of moisture or impurities through the first substrate 110. For example, the buffer layer 111 may be configured as a single layer or multilayer made of silicon oxide (SiOx) or silicon nitride (SiNx). However, the present specification is not limited thereto. The buffer layer 111 may be omitted depending on the type of the first substrate 110 or the type of transistor, but is not limited thereto.

The driving transistor DT is disposed on the buffer layer 111 in each of the plurality of sub pixels SP. The driving transistor DT includes an active layer ACT, a gate electrode GE, a source electrode SE, and a drain electrode DE. In some implementations, although not illustrated in the drawings, other components, such as a switching transistor, a sensing transistor, an emission control transistor, and a storage capacitor, may be additionally disposed in each of the plurality of sub pixels SP, in addition to the driving transistor DT.

The active layer ACT of the driving transistor DT is disposed on the buffer layer 111. The active layer ACT may be disposed to overlap the light shielding layer BSM. The active layer ACT may be formed of a semiconductor material such as an oxide semiconductor, amorphous silicon, or polysilicon, but is not limited thereto. Further, although not illustrated in the drawings, active layers ACT of other transistors, such as a switching transistor, a sensing transistor, and an emission control transistor, may also be formed of a semiconductor material, such as an oxide semiconductor, amorphous silicon, or polysilicon, but are not limited thereto. In addition, the active layers ACT of the driving transistor DT, the switching transistor, the sensing transistor, and the emission control transistor may be formed of the same material or different materials.

A gate insulating layer 112 is disposed on the active layer ACT. The gate insulating layer 112 is an insulating layer which insulates the active layer ACT from the gate electrode GE. For example, the gate insulating layer 112 may be configured by a single layer or a double layer of silicon oxide (SiOx) or silicon nitride (SiNx), but is not limited thereto. In this case, even though in the drawing, it is illustrated that the gate insulating layer 112 is disposed only below the gate electrode GE, the gate insulating layer 112 may be disposed on the entire surface of the first substrate 110, but is not limited thereto.

The gate electrode GE is disposed on the gate insulating layer 112. The gate electrode GE may be disposed to overlap the active layer ACT. The gate electrode GE may be configured by a conductive material such as copper (Cu), aluminum (Al), molybdenum (Mo), nickel (Ni), titanium (Ti), chromium (Cr), or an alloy thereof, but is not limited thereto.

A first interlayer insulating layer 113a and a second interlayer insulating layer 113b are disposed on the gate electrode GE. In the first interlayer insulating layer 113a and the second interlayer insulating layer 113b, a contact hole through which the source electrode SE and the drain electrode DE are connected to the active layer ACT is formed. The first interlayer insulating layer 113a and the second interlayer insulating layer 113b are insulating layers which protect components therebelow and may be configured by a single layer or a double layer of silicon oxide (SiOx) or silicon nitride (SiNx), but are not limited thereto.

The source electrode SE and the drain electrode DE are disposed on the second interlayer insulating layer 113b. The source electrode SE and the drain electrode DE may be electrically connected to the active layer ACT through contact holes formed in the first interlayer insulating layer 113a, the second interlayer insulating layer 113b, and the gate insulating layer 112. Any one of the source electrode SE and the drain electrode DE may be electrically connected to the light emitting element 120. For example, any one of the source electrode SE and the drain electrode DE may supply a driving current to the light emitting element 120 through the first connection electrode CE1 and the first reflective electrode RE1. The source electrode SE and the drain electrode DE may be configured by a conductive material, such as copper (Cu), aluminum (Al), molybdenum (Mo), nickel (Ni), titanium (Ti), chrome (Cr), or an alloy thereof, but are not limited thereto.

A first conductive layer CL1 is disposed on the gate insulating layer 112. The first conductive layer CL1 may be disposed on the same layer as the gate electrode GE and may be formed of the same material as the gate electrode GE, but is not limited thereto. The first conductive layer CL1 is an electrode for applying a constant voltage to the light shielding layer BSM and may be electrically connected to the light shielding layer BSM through contact holes of the gate insulating layer 112 and the buffer layer 111. For example, the light shielding layer BSM is connected to the first conductive layer CL1 so as not to operate as a floating gate and the threshold voltage fluctuation of the driving transistor DT due to the floated light shielding layer BSM may be prevented. The first conductive layer CL1 may be formed of a conductive material, such as copper (Cu), aluminum (Al), molybdenum (Mo), nickel (Ni), titanium (Ti), chromium (Cr), or an alloy thereof, but is not limited thereto.

A second conductive layer CL2 is disposed on the first interlayer insulating layer 113a, and a third conductive layer CL3 electrically connected to the second conductive layer CL2 is disposed on the second interlayer insulating layer 113b. In some implementations, the third conductive layer CL3 may be disposed on the same layer as the source electrode SE and the drain electrode DE and may be formed of the same material as the source electrode SE and the drain electrode DE, but is not limited thereto. For example, the second conductive layer CL2 and the third conductive layer CL3 may be disposed to overlap the gate electrode GE of the driving transistor DT to form a capacitor with the gate electrode GE of the driving transistor DT. The second conductive layer CL2 and the third conductive layer CL3 may be configured by a conductive material such as copper (Cu), aluminum (Al), molybdenum (Mo), nickel (Ni), titanium (Ti), chrome (Cr), or an alloy thereof, but are not limited thereto.

The power line PL is disposed on the second interlayer insulating layer 113b. The power line PL may be configured to transmit a power voltage to the light emitting element 120 of the plurality of sub pixels SP. The power line PL may be made of a conductive material, for example, copper (Cu), aluminum (Al), molybdenum (Mo), nickel (Ni), titanium (Ti), chromium (Cr), or an alloy thereof, but is not limited thereto. The power line PL may be electrically connected to the plurality of light emitting elements 120 through a first connection electrode CE1 and a reflective electrode RE to be described below. The power line PL may be configured as either a low potential power line or a high potential power line depending on the configuration of the pixel circuit. The power line PL may be disposed on the second interlayer insulating layer 113b, but is not limited thereto and may be formed on the same plane as the light shielding layer BSM.

A first planarization layer 114a is disposed on the driving transistor DT, the power line PL, and the second interlayer insulating layer 113b. The first planarization layer 114a may planarize an upper portion of the pixel circuit including the driving transistor DT. The first planarization layer 114a may be configured by a single layer or a double layer, and for example, configured by benzocyclobutene or an acrylic-based organic material, but is not limited thereto.

Next, the reflective electrode RE and the auxiliary electrode AE are disposed on the first planarization layer 114a.

The reflective electrode RE and the auxiliary electrode AE are electrodes which connect the driving transistor DT and the power line PL to the light emitting element 120. For example, the reflective electrode RE and the auxiliary electrode AE may be disposed on the same layer and may be formed of the same material, but are not limited thereto.

The reflective electrode RE may be electrically connected to the power line PL. Accordingly, the reflective electrode RE may be formed of a conductive material. At this time, as illustrated in FIGS. 3A and 3B, all the first sub pixel SP1, the second sub pixel SP2, and the third sub pixel SP3 of the plurality of sub pixels SP may be disposed in the reflective electrode RE. That is, the first sub pixel SP1, the second sub pixel SP2, and the third sub pixel SP3 of the plurality of sub pixels SP may share one reflective electrode RE, but are not limited thereto. Further, the reflective electrode RE is an electrode which reflects light emitted from the light emitting element 120 toward the upper side of the first substrate 110. The reflective electrode RE may include various conductive layers in consideration of light reflection efficiency and resistance. For example, the reflective electrode RE may be made of silver (Ag), aluminum (Al), molybdenum (Mo), titanium (Ti), or an alloy thereof, but is not limited thereto. For another example, the reflective electrode RE may be omitted or replaced with other electrodes or connections depending on the configuration of the pixel circuit.

The auxiliary electrode AE may be electrically connected to the driving transistor DT. The auxiliary electrode AE may electrically connect the light emitting element 120 and the driving transistor DT. In this case, as illustrated in FIGS. 3A and 3B, the auxiliary electrode AE may be individually disposed in each of the first sub pixel SP1, the second sub pixel SP2, and the third sub pixel SP3 of the plurality of sub pixels SP. That is, the first sub pixel SP1, the second sub pixel SP2, and the third sub pixel SP3 of the plurality of sub pixels SP may be individually connected to correspond one of the auxiliary electrodes AE, but are not limited thereto.

In some implementations, the auxiliary electrode AE may be made of a conductive material, for example, silver (Ag), copper (Cu), aluminum (Al), molybdenum (Mo), nickel (Ni), titanium (Ti), chromium (Cr), or an alloy thereof, but is not limited thereto.

An organic insulating layer OIL is disposed on the substrate, particularly, the reflective electrode RE. The organic insulating layer OIL may be disposed to correspond to each of the plurality of sub pixels SP. That is, a plurality of organic insulating layers OIL may be disposed on one reflective electrode RE. The organic insulating layer OIL may fix the light emitting element 120 to the substrate.

The organic insulating layer OIL may be made of, for example, a silicon-based organic insulating material, but is not limited thereto. In some implementations, the organic insulating layer OIL may be formed of a material capable of a photolithography process. Accordingly, the thickness or arrangement area of the organic insulating layer OIL may be easily controlled through a photolithography process.

Referring to FIGS. 3A and 3B, the light emitting element 120 may partially overlap the organic insulating layer OIL in a plan view, and a width of the organic insulating layer OIL in the first direction DR1 may be narrower than a width of the organic insulating layer OIL in the second direction DR2 intersecting the first direction DR1. In this case, as illustrated in FIG. 3B, a planar shape of the organic insulating layer OIL may be a shape extending in the second direction DR2. Therefore, the planar shape of the organic insulating layer OIL may be a shape symmetrical with respect to a virtual straight line V extending in the first direction DR1 from the center of the organic insulating layer OIL. In this case, the planar shape of the organic insulating layer OIL may be symmetrical not only with respect to the first direction DR1, but also with respect to a virtual straight line extending from the center of the organic insulating layer OIL in the second direction DR2. As such, the planar shape of the organic insulating layer OIL may be a shape that satisfies all the requirements of the linear symmetric figure and the point symmetric figure, but is not limited thereto. In this case, the planar shape of the organic insulating layer OIL may be symmetrical with respect to the light emitting element 120 positioned at the center of the organic insulating layer OIL. However, implementations of the present disclosure are not limited to the above-described planar shapes, and a planar shape of only a part of the organic insulating layer OIL overlapping the light emitting element 120 may be symmetrical with respect to the light emitting element 120.

The first direction DR1 may be, for example, a direction in which the first sub pixel SP1, the second sub pixel SP2, and the third sub pixel SP3 of the plurality of sub pixels SP are arranged. That is, the first sub pixel SP1, the second sub pixel SP2, and the third sub pixel SP3 may be disposed along the first direction DR1.

In some implementations, referring to FIGS. 3A to 4C, the organic insulating layer OIL may be disposed under the light emitting element 120, and the light emitting element 120 may partially overlap the organic insulating layer OIL in a plan view. In this case, a part of the light emitting element 120 may not overlap the underlying organic insulating layer OIL, e.g., may extend outside a boundary of the underlying organic insulating layer OIL as shown in the examples of FIGS. 3A, 3B, and 4C. As such, a side surface of this part of the light emitting element 120 will be exposed by not overlapping the organic insulating layer OIL. Further, the lower surface of this part of the light emitting element 120 is partially exposed by not overlapping the organic insulating layer OIL, as shown in the example of FIGS. 3A, 3B, and 4C. Therefore, a lower surface and a side surface of the light emitting element 120, and in particular, a lower surface and a side surface of the first electrode 121 of the light emitting element 120, which are exposed by not overlapping the organic insulating layer OIL, may be in contact with the first connection electrode CE1.

For example, a width of the organic insulating layer OIL in the first direction DR1 may be smaller than a width of the light emitting element 120 in the first direction DR1, so that portions of the light emitting element 120 extend outside and do not overlap the organic insulating layer OIL. Further, a width of the organic insulating layer OIL in the second direction DR2 may be larger than a width of the light emitting element 120 in the second direction DR2, but is not limited thereto. As another example, the width of the organic insulating layer OIL in the second direction DR2 may also be smaller than the width of the light emitting element 120 in the second direction DR2. Accordingly, as shown in the example FIG. 4C, a part of the light emitting element 120 does not overlap the underlying organic insulating layer OIL. As such a side surface of this part of the light emitting element 120 is exposed due to extending outside and not overlapping the underlying organic insulating layer OIL, and a part of the lower surface of the light emitting element 120 is exposed due to extending outside and not overlapping the underlying organic insulating layer OIL. Further, the first connection electrode CE1 is in contact with the side surface and the lower surface of the light emitting element 120, which are exposed by not overlapping the organic insulating layer OIL. That is, the first connection electrode CE1 may be in contact with the first electrode 121 disposed at the lowermost end of the light emitting element 120, namely the part of the light emitting element 120 that is exposed by not overlapping the organic insulating layer OIL.

In addition, as shown in FIGS. 4A and 4B, the remaining part of the lower surface of the light emitting element 120 and the remaining part of the side surface of a part of the light emitting element 120 overlapping the organic insulating layer OIL may be in contact with the organic insulating layer OIL. In this case, even though in FIGS. 4A and 4B, it is illustrated that the organic insulating layer OIL covers all the side surfaces of the first electrode 121 disposed at the lowermost end of the light emitting element 120, the side surfaces of parts of the first electrode 121 may be exposed by not overlapping the organic insulating layer OIL, but is not limited thereto.

The light emitting element 120 is disposed on the organic insulating layer OIL in each of the plurality of sub pixels SP. For example, in the first sub pixel SP1, the second sub pixel SP2, and the third sub pixel SP3, light emitting elements 120 emitting light of different colors may be disposed, respectively, but are not limited thereto. The light emitting element 120 may be any one of a light emitting diode (LED) or a micro light emitting diode (micro LED), but the example implementations of the present disclosure are not limited thereto.

The light emitting element 120 includes a first electrode 121, a first semiconductor layer 122, an emission layer 123, a second semiconductor layer 124, and a second electrode 125.

First, the first electrode 121 is disposed on the organic insulating layer OIL. The first electrode 121 may be disposed at a lowermost end of the light emitting element 120. The first electrode 121 may be in contact with the lower surface of the first semiconductor layer 122. The first electrode 121 is an electrode for electrically connecting the light emitting element 120 to the first connection electrode CE1, the reflective electrode RE, and the power line PL. The light emitting element 120 may be electrically connected to the power line PL through the first electrode 121, the reflective electrode RE, and the first connection electrode CE1. The first electrode 121 may be formed of an opaque conductive material, such as titanium (Ti), gold (Au), silver (Ag), copper (Cu), or an alloy thereof, a transparent conductive material, such as indium tin oxide (ITO) or indium zinc oxide (IZO), or a combination of the opaque conductive material and the transparent conductive material, but is not limited thereto.

The first semiconductor layer 122 is disposed on the first electrode 121, and the second semiconductor layer 124 is disposed on the first semiconductor layer 122. The first semiconductor layer 122 and the second semiconductor layer 124 may be semiconductor layers doped with n-type and p-type impurities. For example, the first semiconductor layer 122 and the second semiconductor layer 124 may be layers doped with n-type and p-type impurities into a material such as gallium nitride (GaN), indium aluminum phosphide (InAlP), or gallium arsenide (GaAs). The n-type impurity may be silicon (Si), germanium (Ge), tin (Sn), and the like, and the p-type impurity may be magnesium (Mg), zinc (Zn), beryllium (Be), and the like, but are not limited thereto.

For example, the first electrode 121 and the first semiconductor layer 122 may be an n-type electrode and an n-type semiconductor layer, and the second electrode 125 and the second semiconductor layer 124 may be a p-type electrode and a p-type semiconductor layer, but are not limited thereto.

The emission layer 123 is disposed between the first semiconductor layer 122 and the second semiconductor layer 124. The emission layer 123 may emit light based on a driving current supplied to the light emitting element 120. For example, the emission layer 123 may emit any one of red light, green light, and blue light. The emission layer 123 may be formed by a single layer or a multi-quantum well (MQW) structure, and for example, may be formed of indium gallium nitride (InGaN) or gallium nitride (GaN), but is not limited thereto.

The second electrode 125 is disposed on the second semiconductor layer 124. The second electrode 125 may be in contact with the top surface of the second semiconductor layer 124. The second electrode 125 is an electrode for electrically connecting the light emitting element 120 to the driving transistor DT. The light emitting element 120 may be electrically connected to the driving transistor DT through the second electrode 125, the second connection electrode CE2, and the auxiliary electrode AE. The second electrode 125 may be made of a transparent conductive material such as indium tin oxide (ITO) or indium zinc oxide (IZO), but is not limited thereto.

Next, in each sub pixel SP, the first connection electrode CE1 is disposed on the top surface of the reflective electrode RE, the top surface of the organic insulating layer OIL, a part of the lower surface of the light emitting element 120, and a part of the side surface of the light emitting element 120. The first connection electrode CE1 is configured to electrically connect the plurality of light emitting elements 120 and the reflective electrode RE of each sub pixel SP. For example, referring to FIG. 3A, the light emitting elements 120 of the first sub pixel SP1, the second sub pixel SP2, and the third sub pixel SP3 of the plurality of sub pixels SP may be electrically connected to the reflective electrode RE by one first connection electrode CE1, but are not limited thereto.

Therefore, the first connection electrode CE1 may be formed of a conductive material, for example, a transparent conductive material such as indium tin oxide (ITO) or indium zinc oxide (IZO), but is not limited thereto.

In some implementations, referring to FIG. 4C, the first connection electrode CE1 is disposed to be in contact with the lower surface of the light emitting element 120 partially exposed by not overlapping the organic insulating layer OIL, that is, the lower surface of the first electrode 121. In this case, the first connection electrode CE1 may have an under-cut cross-section due to a structure in which the width of the organic insulating layer OIL is narrower than the width of the light emitting element 120 disposed on the organic insulating layer OIL, but is not limited thereto.

A second planarization layer 114b is disposed on the reflective electrode RE, the auxiliary electrode AE, the organic insulating layer OIL, the side surface of the light emitting element 120, and the first connection electrode CE1. The second planarization layer 114b may be disposed to surround the side surface of the light emitting element 120. The second planarization layer 114b may be configured by a single layer or a double layer, and for example, configured by benzocyclobutene or an acrylic-based organic material, but is not limited thereto.

A third planarization layer 114c is disposed on the second planarization layer 114b. The third planarization layer 114c may be disposed to cover a top surface of the second planarization layer 114b and a side surface and a top surface of the light emitting element 120. The third planarization layer 114c may be configured as a single layer or multilayer and made of benzocyclobutene or an acrylic-based organic material, for example. However, the present disclosure is not limited thereto.

The second connection electrode CE2 is disposed on the third planarization layer 114c. The second connection electrode CE2 is an electrode which electrically connects the light emitting element 120 and the driving transistor DT. The second connection electrode CE2 may be electrically connected to the auxiliary electrode AE through contact holes formed in the third planarization layer 114c and the second planarization layer 114b. Further, the second connection electrode CE2 may be electrically connected to the light emitting element 120 by contacting the second electrode 125 of the light emitting element 120 exposed from the third planarization layer 114c. Therefore, the second connection electrode CE2 may be formed of a transparent conductive material, for example, a transparent conductive material such as indium tin oxide (ITO) or indium zinc oxide (IZO), but is not limited thereto.

In some implementations, the light emitting element 120 may be electrically connected to the driving transistor DT through the second connection electrode CE2 and the auxiliary electrode AE. For example, referring to FIG. 3A, the light emitting elements 120 of the first sub pixel SP1, the second sub pixel SP2, and the third sub pixel SP3 of the plurality of sub pixels SP may be electrically connected to the respective auxiliary electrodes AE by the second connection electrodes CE2 disposed individually, but are not limited thereto.

Next, a black matrix BM is disposed on the third planarization layer 114c and the second connection electrode CE2. The black matrix BM may be disposed on the third planarization layer 114c in a remaining area excluding an area in which the plurality of light emitting elements 120 is disposed. That is, a portion of the black matrix BM corresponding to upper portions of the plurality of light emitting elements 120 may be opened. Therefore, the black matrix BM may shield light of each of the plurality of sub pixels SP so as not to be mixed with each other. In some implementations, the black matrix BM may be referred to as a black bank, but is not limited thereto. In addition, the black matrix BM absorbs light incident from the outside to the display device 100, thereby minimizing a decrease in visibility due to the reflection of external light from the configuration inside the display device 100. For example, the black matrix BM includes a black component and may be made of an opaque resin including a pigment, but is not limited thereto.

The protective layer 115 is disposed on the black matrix BM. The protective layer 115 is a layer for protecting components below the protective layer 115, and may prevent penetration of moisture or oxygen from the outside. For example, the protective layer 115 may be configured by a single layer or a double layer, and for example, an epoxy-based or acrylic polymer may be used, but is not limited thereto.

In some implementations, although not illustrated, a plurality of color filters and an additional black matrix may be further disposed on the protective layer 115. The plurality of color filters transmits only the desired light of the sub pixels SP to the outside of the display device 100, thereby improving display quality and improving color reproducibility. The additional black matrix may shield light so that light from the plurality of sub pixels SP is not mixed with each other, but is not limited thereto.

The second substrate 116 is disposed on the protective layer 115. The second substrate 116 is a component for supporting and protecting various components included in the display device 100 and may be formed of an insulating material. For example, the second substrate 116 may be made of glass or resin. Further, the second substrate 116 may be made of polymer, plastic, or the like, or may be made of a material having flexibility.

In this case, although not illustrated, a separate adhesive layer for bonding the protective layer 115 and the second substrate 116 may be disposed between the protective layer 115 and the second substrate 116. However, when the second substrate 116 is provided in the form of a film, a separate adhesive layer may not be required, but is not limited thereto.

Among a method of manufacturing a display device by transferring a plurality of light emitting elements to a substrate, a non-contact transfer method in which a plurality of light emitting elements fixed to a temporary substrate is deviated to bring the plurality of light emitting elements down by their own weight to contact an organic insulating material disposed on the target substrate and fixed to the target substrate by the organic insulating material may be used. However, while the plurality of light emitting elements descends by their own weight and comes into contact with the organic insulating material, there may be a problem in that the light emitting element is dropped from the target substrate due to the repulsive force of the organic insulating material. Further, in the process of lowering the light emitting element to the organic insulating material, the light emitting element may be excessively buried in the organic insulating material due to the weight and the descending speed of the light emitting element. At this time, the lower electrode of the light emitting element is not exposed to the outside, but may be covered by an organic insulating material. In this case, since electrical connection through the lower electrode of the light emitting element is impossible, poor connection of the light emitting element may occur.

Accordingly, in the display device 100 according to the example implementation of the present disclosure, the light emitting element 120 partially overlaps the organic insulating layer OIL, particularly, the organic insulating layer OIL has a portion that is partially narrower than the light emitting element 120, thereby preventing the light emitting element from being separated in the non-contact transfer method, and stably connecting the side surface of the light emitting element 120 and the first connection electrode CE1.

Specifically, in the display device 100 according to the example implementation of the present disclosure, the organic insulating layer OIL may have a width in the first direction DR1 smaller than a width in the second direction DR2 intersecting the first direction DR1. That is, the planar shape of the organic insulating layer OIL may be a shape extending in the second direction DR2. In this case, a width of the organic insulating layer OIL in the first direction DR1 may be smaller than a width of the light emitting element 120 in the first direction DR1. That is, the organic insulating layer OIL may be disposed under the light emitting element 120 and the light emitting element 120 may partially overlap the organic insulating layer OIL. In this case, a part of the light emitting element 120 may not overlap the organic insulating layer OIL and a side surface of this part will be exposed from the organic insulating layer OIL. Further, the organic insulating layer OIL partially exposes the lower surface of the light emitting element 120, and the first connection electrode CE1 may be in contact with the lower surface and the side surface of the light emitting element 120 exposed by not overlapping the organic insulating layer OIL. Therefore, the first connection electrode CE1 may be in contact with the first electrode 121 disposed at the lowermost end of the light emitting element 120 exposed by not overlapping the organic insulating layer OIL. Accordingly, the first electrode 121 of the light emitting element 120 may be disposed to be at least partially in contact with the first connection electrode CE1 through a portion of the first electrode non-overlapping and exposed from the organic insulating layer OIL. Accordingly, in the display device 100 according to the example implementation of the present disclosure, the light emitting element 120 partially overlaps the organic insulating layer OIL, particularly, the organic insulating layer OIL has a portion that is partially narrower than the light emitting element 120 so that the side surface of the light emitting element 120 and the first connection electrode CE1 may be stably connected to each other and the light emitting element 120 may be stably connected to the first substrate 110. Accordingly, since the light emitting element having a poor connection is minimized, the production yield may be improved.

In some implementations, in the display device according to the example implementation of the present disclosure, the light emitting element 120 partially overlaps the organic insulating layer OIL, particularly, the organic insulating layer OIL has a portion that is partially narrower than the light emitting element 120, thereby minimizing the repulsive force caused by the organic insulating layer OIL during the transfer process of the light emitting element 120.

Specifically, in the display device according to the example implementation of the present disclosure, the light emitting element 120 partially overlaps the organic insulating layer OIL, particularly, the organic insulating layer OIL is partially disposed to have a narrower width than the light emitting element 120. Accordingly, a contact area between the organic insulating layer OIL and the light emitting element 120 may be reduced during the transfer process of the light emitting element 120. During the transfer process of the light emitting element 120, the repulsive force of the organic insulating layer OIL against the light emitting element 120 is minimized to stably fix the light emitting element 120 to the organic insulating layer OIL. Accordingly, in the display device according to the example implementation of the present disclosure, the light emitting element 120 partially overlaps the organic insulating layer OIL, e.g., the organic insulating layer OIL has a part that is partially narrower than the light emitting element 120 so that the repulsive force caused by the organic insulating layer OIL during the transfer process of the light emitting element 120 may be minimized. Therefore, the light emitting element 120 may be stably seated on the organic insulating layer OIL, and the light emitting element having a poor connection may be minimized, thereby improving the production yield.

Further, in the display device according to the example implementation of the present disclosure, the organic insulating layer OIL is disposed symmetrically so that the light emitting element 120 may be stably seated on the organic insulating layer OIL. For example, the planar shape of the organic insulating layer OIL may be a shape extending in the second direction DR2. Accordingly, the planar shape of the organic insulating layer OIL may be a shape symmetrical with respect to the virtual straight line V extending in the first direction DR1 from the center of the organic insulating layer OIL. In this case, the planar shape of the organic insulating layer OIL may be symmetrical with respect to the light emitting element 120 positioned at the center of the organic insulating layer OIL. However, the present disclosure is not limited to the above planar shapes, and a planar shape of a part of the organic insulating layer OIL overlapping the light emitting element 120 may be symmetrical with respect to the light emitting element 120. Therefore, during the process of transferring the light emitting element 120, the light emitting element 120 may be stably seated on the part of the organic insulating layer OIL having a symmetrical shape during the process of lowering the light emitting element 120 onto the organic insulating layer OIL, and the light emitting element having a poor connection may be minimized, thereby improving the production yield.

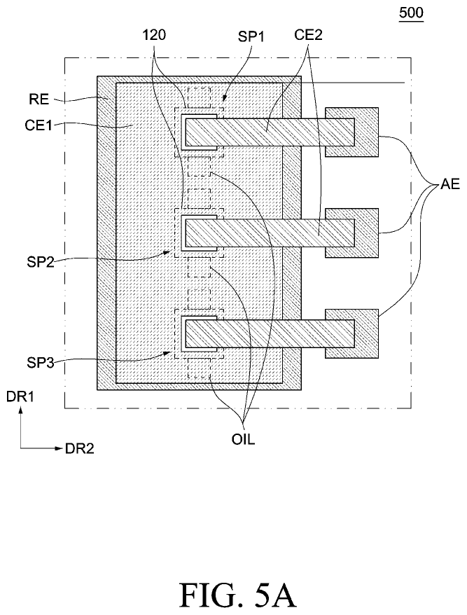

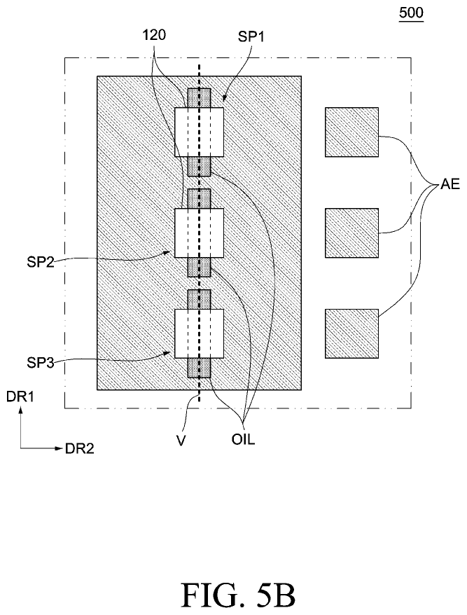

FIGS. 5A and 5B are enlarged top plan views of sub pixels of a display device according to another implementation of the present disclosure. The only difference between a display device 500 of FIGS. 5A and 5B and the display device 100 of FIGS. 1 to 4C is a shape of an organic insulating layer OIL, but other configurations are substantially the same, so that a redundant description will be omitted.

Referring to FIGS. 5A and 5B, a planar shape of the organic insulating layer OIL may be a shape extending in the first direction DR1. For example, the first direction DR1 may be a direction in which the first sub pixel SP1, the second sub pixel SP2, and the third sub pixel SP3 of the plurality of sub pixels SP are arranged, but is not limited thereto.

A width of the organic insulating layer OIL in the second direction DR2 may be narrower than a width in the first direction DR1. That is, the planar shape of the organic insulating layer OIL may be a shape extending in the first direction DR1. Thus, a width of the organic insulating layer OIL in the second direction DR2 may be smaller than a width of the light emitting element 120 in the second direction DR2. That is, in the first direction DR1, the width of the organic insulating layer OIL may be wider than the width of the light emitting element 120, but is not limited thereto. For another example, in the first direction DR1, the width of the organic insulating layer OIL may also be narrower than the width of the light emitting element 120.

In the display device 500 according to another example implementation of the present disclosure, the light emitting element 120 partially overlaps the organic insulating layer OIL, particularly, the organic insulating layer OIL has a part that is partially narrower than the light emitting element 120 so that the side surface of the light emitting element 120 and the first connection electrode CE1 may be stably connected.

Specifically, in the display device 500 according to another example implementation of the present disclosure, the organic insulating layer OIL may have a width in the second direction DR2 smaller than a width in the first direction DR1. That is, the planar shape of the organic insulating layer OIL may be a shape extending in the first direction DR1. Accordingly, the organic insulating layer OIL may be partially disposed below the light emitting element 120 to expose the lower surface of the light emitting element 120 and the side surface of a part of the light emitting element 120 non-overlapping the organic insulating layer OIL, and the lower surface and the side surface of the light emitting element 120 exposed from the organic insulating layer OIL, that is, the lower surface and the side surface of the first electrode 121 may be disposed to be in contact with the first connection electrode CE1. Accordingly, in the display device 500 according to another example implementation of the present disclosure, the light emitting element 120 partially overlaps the organic insulating layer OIL, e.g., the organic insulating layer OIL has a portion that is partially narrower than the light emitting element 120 so that the side surface of the light emitting element 120 and the first connection electrode CE1 may be stably connected to each other and the light emitting element 120 may be stably connected to the first substrate 110. Accordingly, since the light emitting element having a poor connection is minimized, the production yield may be improved.

In some implementations, in the display device 500 according to another example implementation of the present disclosure, the light emitting element 120 may partially overlap the organic insulating layer OIL, e.g., the organic insulating layer OIL may have a part in which the organic insulating layer OIL is partially narrower than the light emitting element 120, but is disposed symmetrically, such that the light emitting element 120 may be stably seated on the organic insulating layer OIL. For example, the planar shape of the organic insulating layer OIL may be a shape extending in the first direction DR1. Accordingly, the planar shape of the organic insulating layer OIL may be a shape symmetrical with respect to the virtual straight line V extending in the first direction DR1 from the center of the organic insulating layer OIL. In this case, the planar shape of the organic insulating layer OIL may be symmetrical with respect to the light emitting element 120 positioned at the center of the organic insulating layer OIL. However, the present disclosure is not limited to the above planar shapes, and a planar shape of a part of the organic insulating layer OIL overlapping the light emitting element 120 may be symmetrical with respect to the light emitting element 120. Therefore, during the process of transferring the light emitting element 120, the light emitting element 120 may be stably seated on the part of the organic insulating layer OIL having a symmetrical shape during the process of lowering the light emitting element 120 onto the organic insulating layer OIL, and the light emitting element having a poor connection may be minimized, thereby improving the production yield.

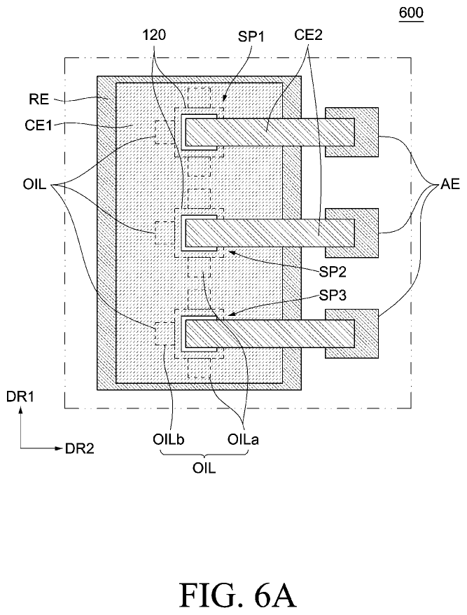

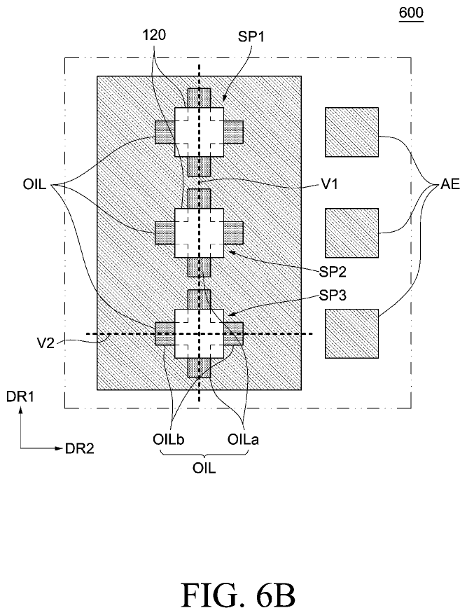

FIGS. 6A and 6B are enlarged top plan views of sub pixels of a display device according to still another implementation of the present disclosure. The only difference between a display device 600 of FIGS. 6A and 6B and the display device 100 of FIGS. 1 to 4C is a shape of an organic insulating layer OIL, but other configurations are substantially the same, so that a redundant description will be omitted.

Referring to FIGS. 6A and 6B, a planar shape of the organic insulating layer OIL may extend along a first direction DR1 and a second direction DR2 crossing the first direction DR1. For example, the first direction DR1 may be a direction in which the first sub pixel SP1, the second sub pixel SP2, and the third sub pixel SP3 of the plurality of sub pixels SP are arranged, but is not limited thereto.

The organic insulating layer OIL includes a first portion OILa that is a portion extending along the first direction DR1 and a second portion OILb that is a portion extending from the first portion OILa along the second direction DR2. For example, the planar shape of the organic insulating layer OIL may be a + (a cross or a plus sign) shape, but is not limited thereto.

In some implementations, the planar shape of the organic insulating layer OIL may be a shape symmetrical with respect to a first virtual straight line V1 extending in the first direction DR1 from the center of the organic insulating layer OIL and a second virtual straight line V2 extending in the second direction DR2 from the center of the organic insulating layer OIL. That is, the planar shape of the organic insulating layer OIL may be a shape that satisfies all the requirements of the linear symmetric figure and the point symmetric figure, but is not limited thereto.

In the display device 600 according to still another example implementation of the present disclosure, the light emitting element 120 partially overlaps the organic insulating layer OIL, particularly, the organic insulating layer OIL has a part that is partially narrower than the light emitting element 120 so that the side surface of the light emitting element 120 and the first connection electrode CE1 may be stably connected.

Specifically, in the display device 600 according to still another example implementation of the present disclosure, the planar shape of the organic insulating layer OIL may be a shape extending along the first direction DR1 and the second direction DR2, respectively. Accordingly, the organic insulating layer OIL may be partially disposed below the light emitting element 120 to expose the lower surface of the light emitting element 120 and the side surface of a part of the light emitting element 120 non-overlapping the organic insulating layer OIL, and the lower surface and the side surface of the light emitting element 120 exposed from the organic insulating layer OIL, that is, the lower surface and the side surface of the first electrode 121 may be disposed to be in contact with the first connection electrode CE1. Accordingly, in the display device 600 according to still another example implementation of the present disclosure, the light emitting element 120 partially overlaps the organic insulating layer OIL, e.g., the organic insulating layer OIL has a portion that is partially narrower than the light emitting element 120 so that the side surface of the light emitting element 120 and the first connection electrode CE1 may be stably connected to each other and the light emitting element 120 may be stably connected to the first substrate 110. Accordingly, since the light emitting element having a poor connection is minimized, the production yield may be improved.

In some implementations, in the display device 600 according to still another example implementation of the present disclosure, the light emitting element 120 may partially overlap the organic insulating layer OIL, e.g., the organic insulating layer OIL may have a part in which the organic insulating layer OIL is partially narrower than the light emitting element 120, but is disposed symmetrically, such that the light emitting element 120 may be stably seated on the organic insulating layer OIL. For example, the planar shape of the organic insulating layer OIL may be a shape extending in each of the first direction DR1 and the second direction DR2. Accordingly, the planar shape of the organic insulating layer OIL may be a shape symmetrical to the first virtual straight line V1 extending in the first direction DR1 from the center of the organic insulating layer OIL and the second virtual straight line V2 extending in the second direction DR2 from the center of the organic insulating layer OIL. In this case, the planar shape of the organic insulating layer OIL may be symmetrical with respect to the light emitting element 120 positioned at the center of the organic insulating layer OIL. However, the present disclosure is not limited to the above planar shapes, and a planar shape of a part of the organic insulating layer OIL overlapping the light emitting element 120 may be symmetrical with respect to the light emitting element 120. Therefore, in the process where the light emitting element 120 descends onto the organic insulating layer OIL during the transfer process of the light emitting element 120, the light emitting element 120 may be more stably seated on the part of the organic insulating layer OIL having a symmetrical shape, and the light emitting element having a defective connection may be minimized, thereby further improving the production yield.

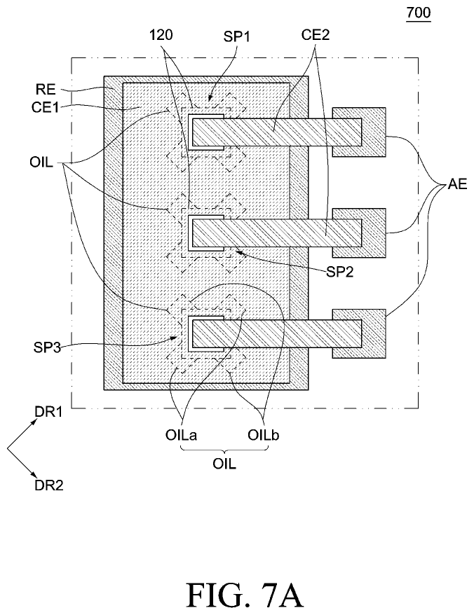

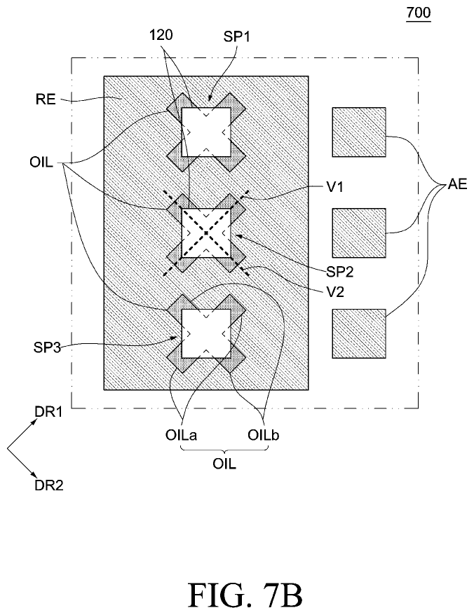

FIGS. 7A and 7B are enlarged top plan views of sub pixels of a display device according to still another implementation of the present disclosure. The only difference between a display device 700 of FIGS. 7A and 7B and the display device 100 of FIGS. 1 to 4C is a shape of an organic insulating layer OIL, but other configurations are substantially the same, so that a redundant description will be omitted.

Referring to FIGS. 7A and 7B, a planar shape of the organic insulating layer OIL may extend along a first direction DR1 and a second direction DR2 crossing the first direction DR1. For example, the first direction DR1 may be a diagonal direction relative to a direction in which the first sub pixels SP1, the second sub pixels SP2, and the third sub pixels SP3 of the plurality of sub pixels SP are arranged, but is not limited thereto.

The organic insulating layer OIL includes a first portion OILa that is a portion extending along the first direction DR1 and a second portion OILb that is a portion extending from the first portion OILa along the second direction DR2. For example, the planar shape of the organic insulating layer OIL may be an X shape, but is not limited thereto.

In some implementations, the planar shape of the organic insulating layer OIL may be a shape symmetrical with respect to a first virtual straight line V1 extending in the first direction DR1 from the center of the organic insulating layer OIL and a second virtual straight line V2 extending in the second direction DR2 from the center of the organic insulating layer OIL. That is, the planar shape of the organic insulating layer OIL may be a shape that satisfies all the requirements of the linear symmetric figure and the point symmetric figure, but is not limited thereto.

In the display device 700 according to still another example implementation of the present disclosure, the light emitting element 120 partially overlaps the organic insulating layer OIL, particularly, the organic insulating layer OIL has a part that is partially narrower than the light emitting element 120 so that the side surface of the light emitting element 120 and the first connection electrode CE1 may be stably connected.

Specifically, in the display device 700 according to still another example implementation of the present disclosure, the planar shape of the organic insulating layer OIL may be a shape extending along the first direction DR1 and the second direction DR2, respectively. Accordingly, the organic insulating layer OIL may be partially disposed below the light emitting element 120 to expose the lower surface of the light emitting element 120 and the side surface of a part of the light emitting element 120 non-overlapping the organic insulating layer OIL, and the lower surface and the side surface of the light emitting element 120 exposed from the organic insulating layer OIL, that is, the lower surface and the side surface of the first electrode 121 may be disposed to be in contact with the first connection electrode CE1. Accordingly, in the display device 700 according to still another example implementation of the present disclosure, the light emitting element 120 partially overlaps the organic insulating layer OIL, e.g., the organic insulating layer OIL has a portion that is partially narrower than the light emitting element 120 so that the side surface of the light emitting element 120 and the first connection electrode CE1 may be stably connected to each other and the light emitting element 120 may be stably connected to the first substrate 110. Accordingly, since the light emitting element having a poor connection is minimized, the production yield may be improved.

In some implementations, in the display device 700 according to still another example implementation of the present disclosure, the light emitting element 120 may partially overlap the organic insulating layer OIL, e.g., the organic insulating layer OIL may have a part in which the organic insulating layer OIL is partially narrower than the light emitting element 120, but is disposed symmetrically, such that the light emitting element 120 may be stably seated on the organic insulating layer OIL. For example, the planar shape of the organic insulating layer OIL may be a shape extending in each of the first direction DR1 and the second direction DR2. Accordingly, the planar shape of the organic insulating layer OIL may be a shape symmetrical to the first virtual straight line V1 extending in the first direction DR1 from the center of the organic insulating layer OIL and the second virtual straight line V2 extending in the second direction DR2 from the center of the organic insulating layer OIL. In this case, the planar shape of the organic insulating layer OIL may be symmetrical with respect to the light emitting element 120 positioned at the center of the organic insulating layer OIL. However, the present disclosure is not limited to the above planar shapes, and a planar shape of a part of the organic insulating layer OIL overlapping the light emitting element 120 may be symmetrical with respect to the light emitting element 120. Therefore, in the process where the light emitting element 120 descends onto the organic insulating layer OIL during the transfer process of the light emitting element 120, the light emitting element 120 may be more stably seated on the part of the organic insulating layer OIL having a symmetrical shape, and the light emitting element having a defective connection may be minimized, thereby further improving the production yield.

The example implementations of the present disclosure can also be described as follows:

According to an implementation of the present disclosure, a display device includes a substrate, an organic insulating layer disposed on the substrate, a light emitting element disposed on the organic insulating layer, and a connection electrode configured to cover the organic insulating layer, and the light emitting element partially overlaps the organic insulating layer and the connection electrode electrically connects a side surface of a part of the light emitting element that does not overlap the organic insulating layer.

According to another aspect of the present disclosure, a width of the organic insulating layer in a first direction is smaller than a width of the light emitting element in a first direction; and/or a width of the organic insulating layer in a second direction crossing the first direction may be smaller than a width of the light emitting element in the second direction.

According to yet another aspect of the present disclosure, a part of the lower surface of the light emitting element may be exposed by not overlapping the organic insulating layer, and the connection electrode may be in contact with the part of the lower surface of the light emitting element that is exposed by not overlapping the organic insulating layer.

According to yet another aspect of the present disclosure, the light emitting element includes a first electrode disposed at the lowermost end of the light emitting element, and the connection electrode may be in contact with a lower surface of the first electrode that is exposed by not overlapping the organic insulating layer.

According to yet another aspect of the present disclosure, the organic insulating layer may be in contact with the remaining part of the lower surface of the light emitting element and a side surface of a part of the light emitting element that overlaps the organic insulating layer.

According to yet another aspect of the present disclosure, the planar shape of the organic insulating layer may be a shape extending along a first direction or a second direction crossing the first direction.

According to yet another aspect of the present disclosure, the planar shape of the organic insulating layer may be a shape extending along a first direction and the second direction intersecting the first direction, respectively.

According to yet another aspect of the present disclosure, the planar shape of the organic insulating layer may be a + shape or an X shape.

According to yet another aspect of the present disclosure, the display device may further comprise a reflective electrode disposed on the substrate, and the organic insulating layer may be disposed on the reflective electrode, and the connection electrode may electrically connect the reflective electrode and the light emitting element.

According to yet another aspect of the present disclosure, the organic insulating layer may expose a side surface of a part of the first electrode overlapping the organic insulating layer, and the connection electrode may be in contact with the side surface of the part of the first electrode that is exposed by not overlapping the organic insulating layer.

According to yet another aspect of the present disclosure, a planar shape of a part of the organic insulating layer overlapping the light emitting element may be a shape symmetrical with respect to the light emitting element.

According to another implementation of the present disclosure, a display device includes a substrate on which a first sub pixel, a second sub pixel, and a third sub pixel are disposed, a plurality of organic insulating layers disposed in the first sub pixel, the second sub pixel, and the third sub pixel on the substrate, a plurality of light emitting elements disposed in the first sub pixel, the second sub pixel, and the third sub pixel on the plurality of organic insulating layers, and a connection electrode electrically connecting the plurality of light emitting elements.

A part of a lower surface of each of the plurality of light emitting elements may be exposed by not overlapping the corresponding one of the plurality of organic insulating layers, and the connection electrode may be in contact with the part of the lower surface of each of the plurality of light emitting elements that is exposed by not overlapping the corresponding one of the plurality of organic insulating layers.

According to another aspect of the present disclosure, the plurality of organic insulating layers may contact the remaining part of the lower surfaces of the plurality of light emitting elements and cover a part of the side surface extending from the lower surfaces of the plurality of light emitting elements.

According to yet another aspect of the present disclosure, the planar shape of the plurality of organic insulating layers may be a shape symmetrical with respect to a virtual straight line extending in the first direction from the center of each of the plurality of organic insulating layers.

According to yet another aspect of the present disclosure, each of the plurality of organic insulating layers may have a width in the first direction narrower than a width thereof in a second direction intersecting the first direction.

According to yet another aspect of the present disclosure, in a plan view, the plurality of light emitting elements may be positioned at the center of each of the plurality of organic insulating layers, and each of the plurality of organic insulating layers may have a shape symmetrical with respect to the light emitting element positioned at the center.

According to yet another aspect of the present disclosure, each of the plurality of organic insulating layers may include a first portion extending along the first direction and a second portion extending from the first portion along a second direction intersecting the first direction.

According to yet another aspect of the present disclosure, the planar shape of the plurality of organic insulating layers may be a shape symmetrical with respect to a virtual straight line extending in the second direction from the center of each of the plurality of organic insulating layers.

According to yet another aspect of the present disclosure, the first sub pixel, the second sub pixel, and the third sub pixel may be disposed along the first direction, and a planar shape of the plurality of organic insulating layers may be a shape extending in the first direction and/or the second direction intersecting the first direction.

According to yet another aspect of the present disclosure, a planar shape of the plurality of organic insulating layers may be a shape extending in a first direction and/or a second direction intersecting the first direction, the first direction being a diagonal direction relative to a direction along which the first sub pixel, the second sub pixel, and the third sub pixel are disposed.

Although the example implementations of the present disclosure have been described in detail with reference to the accompanying drawings, the present disclosure is not limited thereto and may be embodied in various forms without departing from the technical concept of the present disclosure. Therefore, the example implementations of the present disclosure are provided for illustrative purposes only but not intended to limit the technical concept of the present disclosure. The scope of the technical concept of the present disclosure is not limited thereto. Therefore, it should be understood that the above-described implementations are illustrative in all implementations and do not limit the present disclosure.

What is claimed is:

1. A display device comprising:
a substrate;
an organic insulating layer disposed on the substrate;
a light emitting element disposed on the organic insulating layer; and
a connection electrode configured to cover the organic insulating layer in a plan view,
wherein the light emitting element partially overlaps the organic insulating layer in the plan view,
wherein a first part of the light emitting element does not overlap the organic insulating layer in the plan view, and
wherein the connection electrode is electrically connected to a side surface of the first part of the light emitting element that does not overlap the organic insulating layer in the plan view.

2. The display device according to claim 1,
wherein in the plan view, a width of the organic insulating layer in a first direction is smaller than a width of the light emitting element in the first direction; and/or
wherein in the plan view, a width of the organic insulating layer in a second direction crossing the first direction is smaller than a width of the light emitting element in the second direction.

3. The display device according to claim 1, wherein a lower surface of the first part of the light emitting element is exposed by not overlapping the organic insulating layer, and
wherein the connection electrode is in contact with the lower surface of the first part of the light emitting element that is exposed by not overlapping the organic insulating layer.

4. The display device according to claim 3, wherein the light emitting element includes a first electrode disposed at a lowermost end of the light emitting element,
wherein a lower surface of a part of the first electrode is exposed by not overlapping the organic insulating layer, and
wherein the connection electrode is in contact with the lower surface of the part of the first electrode that is exposed by not overlapping the organic insulating layer.

5. The display device according to claim 3, wherein a second part of the light emitting element overlaps the organic insulating layer in the plan view, and
wherein the organic insulating layer contacts a lower surface and a side surface of the second part of the light emitting element that overlaps the organic insulating layer.

6. The display device according to claim 1, wherein in the plan view, the organic insulating layer has a shape extending along a first direction or along a second direction crossing the first direction.

7. The display device according to claim 1, wherein in the plan view, the organic insulating layer has a shape extending along both a first direction and along a second direction intersecting the first direction.

8. The display device according to claim 7, wherein in the plan view, the organic insulating layer has a + shape or an X shape.

9. The display device according to claim 1, further comprising:
a reflective electrode disposed on the substrate,
wherein the organic insulating layer is disposed on the reflective electrode, and
wherein the connection electrode electrically connects the reflective electrode and the light emitting element.

10. The display device according to claim 4, wherein a side surface of the part of the first electrode is exposed by not overlapping the organic insulating layer, and
wherein the connection electrode is in contact with the side surface of the part of the first electrode that is exposed by not overlapping the organic insulating layer.

11. The display device according to claim 1, wherein in the plan view, a part of the organic insulating layer overlapping the light emitting element has a shape that is symmetrical with respect to the light emitting element.

12. A display device comprising:
a substrate on which a first sub pixel, a second sub pixel, and a third sub pixel are disposed;
a plurality of organic insulating layers disposed on the substrate in the first sub pixel, the second sub pixel, and the third sub pixel, respectively;
a plurality of light emitting elements disposed on the plurality of organic insulating layers in the first sub pixel, the second sub pixel, and the third sub pixel, respectively; and
a connection electrode electrically connecting the plurality of light emitting elements,
wherein a first part of each of the plurality of light emitting elements does not overlap a corresponding one of the plurality of organic insulating layers in a plan view,
wherein a lower surface of the first part of each of the plurality of light emitting elements is exposed by not overlapping the corresponding one of the plurality of organic insulating layers in the plan view, and
wherein the connection electrode is in contact with the lower surface of the first part of each of the plurality of light emitting elements that is exposed by not overlapping the corresponding one of the plurality of organic insulating layers.

13. The display device according to claim 12, wherein a second part of each of the plurality of light emitting elements overlaps the corresponding one of the plurality of organic insulating layers in the plan view,
wherein a lower surface of the second part of each of the plurality of light emitting elements contacts the corresponding one of the plurality of organic insulating layers, and
wherein a side surface of the second part, extending from the lower surface of the second part of each of the plurality of light emitting elements, is covered by the corresponding one of the plurality of organic insulating layers.

14. The display device of claim 12, wherein in the plan view, each of the plurality of organic insulating layers has a shape that is symmetrical with respect to a virtual straight line extending in a first direction from a center of each of the plurality of organic insulating layers.

15. The display device according to claim 14, wherein in the plan view, each of the plurality of organic insulating layers has a width in the first direction which is smaller than a width thereof in a second direction intersecting the first direction.

16. The display device according to claim 12, wherein in a plan view, the plurality of light emitting elements is positioned at a center of each of the plurality of organic insulating layers, and each of the plurality of organic insulating layers has a shape that is symmetrical with respect to a light emitting element positioned at the center.

17. The display device according to claim 14, wherein each of the plurality of organic insulating layers includes:
a first portion extending along the first direction; and
a second portion extending from the first portion along a second direction which intersects the first direction.

18. The display device of claim 17, wherein in the plan view, each of the plurality of organic insulating layers has a shape that is symmetrical with respect to a virtual straight line extending in the second direction from the center of each of the plurality of organic insulating layers.

19. The display device of claim 12, wherein the first sub pixel, the second sub pixel, and the third sub pixel are disposed along a first direction, and
wherein in the plan view, the plurality of organic insulating layers has a shape extending in the first direction and/or a second direction intersecting the first direction.

20. The display device of claim 12, wherein
in the plan view, the plurality of organic insulating layers has a shape extending in a first direction and/or a second direction intersecting the first direction, the first direction being a diagonal direction relative to a direction along which the first sub pixel, the second sub pixel, and the third sub pixel are disposed.
